(19) United States
(12) Patent Application Publication
(10) Pub. No.: US 2011/0156084 A1
(43) Pub. Date: Jun. 30, 2011

(54) ORGANIC LIGHT EMITTING DIODE LIGHTING APPARATUS

(75) Inventors: Sung-Jin Choi, Yongin-city (KR); Ok-Keun Song, Yongin-city (KR); Young-Mo Koo, Yongin-city (KR)

(73) Assignee: Samsung Mobile Display Co., Ltd., Yongin-city (KR)

(21) Appl. No.: 12/895,201

(22) Filed: Sep. 30, 2010

(30) Foreign Application Priority Data
Dec. 28, 2009 (KR) 10-2009-0132205

(51) Int. Cl. H01L 33/62

(52) U.S. Cl. 257/99; 257/E33.059

(57) ABSTRACT

An organic light emitting diode lighting apparatus is disclosed. In one embodiment, the apparatus includes: i) a substrate main body including a light emitting region and a sealing region surrounding the light emitting region, ii) an organic light emitting diode formed over the substrate main body and iii) a sealant formed over the sealing region of the substrate main body, wherein the sealant includes a conductive member electrically connected to the organic light emitting diode. The apparatus may further include a printed circuit board bonded to the substrate main body by the sealant to seal and cover the organic light emitting diode, wherein the printed circuit board includes external input terminals which directly contact the conductive member.

### RELATED APPLICATIONS

This application claims priority to and the benefit of Korean Patent Application No. 10-2009-0132205 filed in the Korean Intellectual Property Office on Dec. 28, 2009, the entire content of which is incorporated herein by reference.

### BACKGROUND

1. Field

The disclosed technology generally relates to a lighting apparatus. More particularly, the described technology generally relates to an organic light emitting diode (OLED) display or OLED lighting apparatus using an OLED.

2. Description of the Related Technology

OLED displays use light emitted from an OLED. The OLED emits light using energy generated when excitons, produced by electron-hole combinations in an organic emission layer, change the status from an excitation state to a ground state.

### SUMMARY

Exemplary embodiments provide an organic light emitting diode lighting apparatus that has a simple structure and improves luminous efficiency.

According to an exemplary embodiment, an organic light emitting diode lighting apparatus includes: a substrate main body including a light emitting region and a sealing region surrounding the light emitting region; an organic light emitting diode formed on the substrate main body; a sealant formed over the sealing region of the substrate main body and including a conductive member connected to the organic light emitting diode; and a printed circuit board bonded to the substrate main body by the sealant to seal and cover the organic light emitting diode and including external input terminals connected to the conductive member.

The external input terminals may include: contact portions formed on one surface of the printed circuit board facing the sealant; pad portions formed on the other surface of the printed circuit board opposed to the one surface; and connecting portions penetrating the printed circuit board and connecting the contact portions and the pad portions.

The organic light emitting diode may further include: a first electrode formed over the light emitting region of the substrate main body and having one end extending to the sealing region; an organic emission layer formed over the first electrode on the light emitting region of the substrate main body; and a second electrode formed over the organic emission layer and having one end extending to the sealing region so as to be spaced apart from the first electrode.

The external input terminals may include a first external input terminal to be connected to the first electrode and a second external input terminal to be connected to the second electrode.

The printed circuit board may further include a first wiring portion connected to the first external input terminal and a second wiring portion connected to the second external input terminal.

The conductive member may be a plurality of conductive balls.

One or more circuit elements may be mounted on the opposite surface of the surface facing the organic light emitting diode of the printed circuit board.

The difference between the two-dimensional area of the substrate main body and the two-dimensional area of the printed circuit board may be less than 10%.

The organic light emitting diode lighting apparatus may further include flexible printed circuit films.

In the organic light emitting diode lighting apparatus, the printed circuit board may be a metal printed circuit board made of a metal material.

The printed circuit board may be depressed at a portion corresponding to the light emitting region of the substrate main body and spaced apart from the organic light emitting diode in the light emitting region.

The light emitting region of the substrate main body may be depressed so that the organic light emitting diode and the printed circuit board are spaced apart from each other in the light emitting region.

In the organic light emitting diode lighting apparatus, the printed circuit board may be made of a material containing at least one of glass and plastic.

The printed circuit board may be depressed at a portion corresponding to the light emitting region of the substrate main body and spaced apart from the organic light emitting diode in the light emitting region.

The light emitting region of the substrate main body may be depressed so that the organic light emitting diode and the printed circuit board are spaced apart from each other in the light emitting region.

According to the exemplary embodiments, the organic light emitting diode lighting apparatus can have a simple structure and improved luminous efficiency. Another aspect is an organic light emitting diode lighting apparatus, comprising: a substrate main body including a light emitting region and a sealing region surrounding the light emitting region; an organic light emitting diode formed over the substrate main body; a sealant formed over the sealing region of the substrate main body, wherein the sealant comprises a conductive member electrically connected to the organic light emitting diode; and a printed circuit board bonded to the substrate main body by the sealant to seal and cover the organic light emitting diode, wherein the printed circuit board comprises external input terminals which directly contact the conductive member.

In the above apparatus, the external input terminals comprise: contact portions formed on one surface of the printed circuit board facing the sealant, wherein the contact portions contact the conductive member of the sealant; pad portions formed on the other surface of the printed circuit board opposed to the one surface; and connecting portions penetrating the printed circuit board and interconnecting the contact portions and the pad portions.

In the above apparatus, the organic light emitting diode further comprises: a first electrode formed over the light emitting region of the substrate main body and having one end extending to the sealing region; an organic emission layer formed over the first electrode and the light emitting region of the substrate main body; and a second electrode formed over the organic emission layer and having one end extending to the sealing region so as to be spaced apart from the first electrode.

In the above apparatus, the external input terminals comprise a first external input terminal to be electrically connected to the first electrode and a second external input terminal to be electrically connected to the second electrode, and wherein first and second terminals are formed on opposing ends of the printed circuit board. In the above apparatus, the printed circuit board further comprises a first wiring portion electrically connected to the first external input terminal and a second wiring portion electrically connected to the second external input terminal. In the above apparatus, the conductive member comprises a plurality of conductive balls.

In the above apparatus, the printed circuit board has first and second surfaces opposing each other, wherein the first surface faces the organic light emitting diode and wherein one or more circuit elements are mounted on the second surface of the printed circuit board. In the above apparatus, the difference between the two-dimensional area of the substrate main body and the two-dimensional area of the printed circuit board is less than about 10%. The above apparatus further comprises flexible printed circuit films electrically connected to the external input terminals. In the above apparatus, the printed circuit board is a metal printed circuit board made of a metal material.

In the above apparatus, the printed circuit board has first and second surfaces opposing each other, wherein the first surface faces the organic light emitting diode and wherein the first surface of the printed circuit board is recessed and spaced apart from the organic light emitting diode in the light emitting region. In the above apparatus, the printed circuit board has first and second surfaces opposing each other, wherein the first surface faces the organic light emitting diode, wherein the substrate main body has first and second surfaces opposing each other, wherein the first surface of the substrate main body faces the first surface of the printed circuit board, wherein the first surface of the printed circuit board is not recessed, and wherein the first surface of the substrate main body is recessed so that the organic light emitting diode and the printed circuit board are spaced apart from each other in the light emitting region.

In the above apparatus, the printed circuit board is made of a material containing at least one of glass and plastic. In the above apparatus, at least one of the first and second electrodes extends to and contacts the sealant, and wherein at least one of the first and second electrodes has a non-linear portion which is formed near the sealant. In the above apparatus, the printed circuit board encapsulates the organic light emitting diode so that the lighting apparatus does not require a separate encapsulation film. In the above apparatus, the printed circuit board is formed of a transparent material so as to transmit light emitted from the organic light emitting diode.

Another aspect is an organic light emitting diode lighting apparatus, comprising: a substrate; an organic light emitting diode formed over the substrate, wherein the organic light emitting diode comprises first and second electrodes and a light emitting layer interposed between the electrodes; and a printed circuit board electrically connected to at least one of the first and second electrodes via a sealant, wherein the printed circuit board is configured to encapsulate the organic light emitting diode, wherein at least one of the first and second electrodes extends to and contacts the sealant. and wherein at least one of the first and second electrodes has a non-linear portion which is formed near the sealant.

In the above apparatus, the sealant comprises a plurality of conductive balls electrically connected to the organic light emitting diode and external input terminals of the printed circuit board. In the above apparatus, the first and second electrodes have first and second non-linear portions, respectively, wherein the substrate has first and second ends opposing each other, wherein the first and second non-linear portions are formed near the first and second ends of the substrate, respectively.

In the above apparatus, the printed circuit board has first and second surfaces opposing each other, wherein the first surface faces the organic light emitting diode, wherein the substrate has first and second surfaces opposing each other, wherein the first surface of the substrate faces the first surface of the printed circuit board, and wherein one of 1) the first surface of the printed circuit board and 2) the first surface of the substrate has a recessed portion configured to accommodate the organic light emitting diode.

### BRIEF DESCRIPTION OF THE DRAWINGS

FIG. 1 is a cross-sectional view showing an organic light emitting diode display according to a first exemplary embodiment.

FIG. 2 is a top plan view of a printed circuit board of the organic light emitting diode lighting apparatus of FIG. 1.

FIG. 3 is a cross-sectional view showing an organic light emitting diode display according to a second exemplary embodiment.

FIG. 4 is a cross-sectional view showing an organic light emitting diode display according to a third exemplary embodiment.

FIG. 5 is a cross-sectional view showing an organic light emitting diode display according to a fourth exemplary embodiment.

### DETAILED DESCRIPTION

OLED displays include a light emitting region for emitting light and a non-light emitting region disposed around the light emitting region. The non-light emitting region includes a sealing region and a pad region for connecting electrodes of the OLED. Here, the area of the non-light emitting region is desirable to decrease to further improve luminous efficiency.

Hereinafter, exemplary embodiments will be described in detail with reference to the accompanying drawings.

Throughout the specification, the same or similar elements are denoted by the same reference numerals. Also, among several exemplary embodiments, exemplary embodiments other than a first exemplary embodiment will be described only with respect to components differing from those of the first exemplary embodiment.

In the drawings, the sizes and thicknesses of the components are merely shown for convenience of explanation, and therefore the present invention is not necessarily limited to the illustrations described and shown herein.

In the drawings, the thickness of layers, films, panels, regions, etc., may be exaggerated for clarity. In the drawings, the thicknesses of some layers and areas are exaggerated for convenience of explanation. It will be understood that when an element such as a layer, film, region, or substrate is referred to as being “on” another element, it can be directly on the other element or intervening elements may also be present.

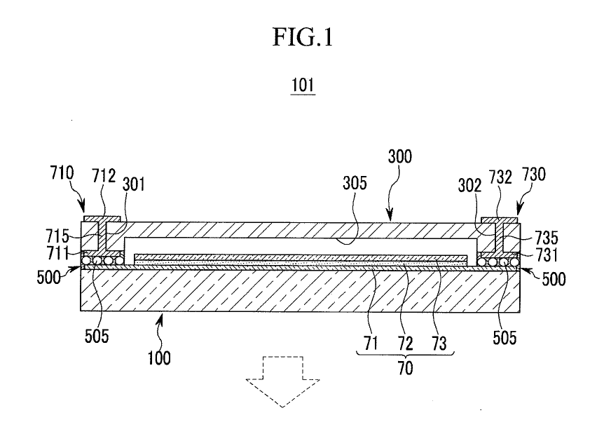

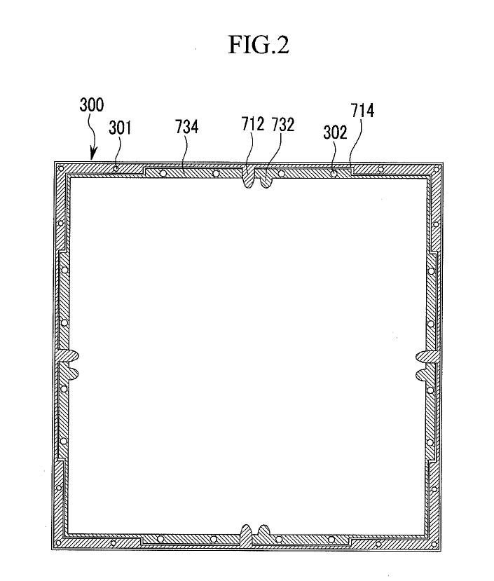

Hereinafter, an organic light emitting diode lighting apparatus 101 according to a first exemplary embodiment will be described with reference to FIGS. 1 to 2.

As shown in FIG. 1, the organic light emitting diode lighting apparatus 101 includes a substrate main body 100, an organic light emitting diode 70, a sealant 500, and a printed circuit board (PCB) 300.

The substrate main body 100 may be formed as a transparent insulating made of, for example, glass, quartz, ceramic, etc., or may be formed as a transparent flexible substrate made of plastic, etc.

Moreover, the substrate main body 100 is divided into a light emitting region and a sealing region surrounding the light emitting region. The organic light emitting diode 70 is formed on the light emitting region, and the sealant 500 is formed on the sealing region. The organic light emitting diode 70 includes a first electrode 71, an organic emission layer 72, and a second electrode 73.

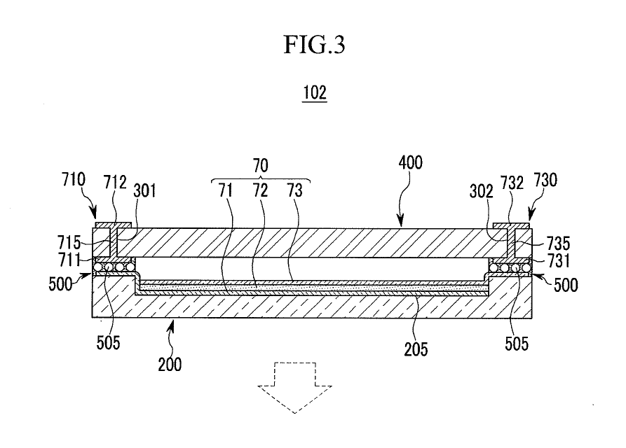

In one embodiment, the first electrode 71 is formed over the light emitting region of the substrate main body 100, and at least one end thereof extends to the sealing region (See FIGS. 1 and 3-5). The organic emission layer 72 is formed on or over the first electrode 71 over the light emitting region of the substrate main body 100. In one embodiment, the second electrode 73 is formed on or over the organic emission layer 72, and at least one end thereof extends to the sealing region so as to be spaced apart from the first electrode 71(See FIGS. 3-5). In one embodiment, as shown in FIG. 1, both ends of the first electrode 71 extend to the sealing region whereas the second electrode 73 does not extend to the sealing region. In this embodiment, neither of the first and second electrodes 71 and 73 includes a curved or non-linear portion.

In one embodiment, the first electrode 71 is a positive (+) electrode serving as a hole injection electrode. In one embodiment, the second electrode 73 is a negative (−) electrode serving as an electron injection electrode. However, the first exemplary embodiment is not limited thereto. Therefore, the first electrode 71 may serve as an electron injection electrode, and the second electrode 73 may serve as a hole injection electrode.

In one embodiment, the first electrode 71 is formed of a transparent conductive film or a semi-transmissive film, and the second electrode 73 is formed of a reflective film.

The transparent conductive film may be made of at least one of the following: indium tin oxide (ITO), indium zinc oxide (IZO), zinc oxide (ZnO), Indium oxide (In₂O₃), etc. The transparent conductive film has a relatively high work function. Thus, the first electrode 71 formed of a transparent conductive film can perform hole injection smoothly. Moreover, in the case where the first electrode 71 is formed of a transparent conductive film, the organic light emitting diode lighting apparatus 101 may further include an auxiliary electrode made of a metal having relatively low resistivity in order to compensate for the relatively high resistivity of the first electrode 71.

In one embodiment, the reflective film and the semi-transmissive film are made of at least one metal of magnesium (Mg), silver (Ag), gold (Au), calcium (Ca), lithium (Li), chromium (Cr), and aluminum (Al), or an alloy thereof. The same material can be used to form the reflective film and the semi-transmissive film. The difference between the reflective film and the semi-transmissive film is the thickness of the films. In one embodiment, the semi-transmissive film has a thickness of less than about 200 nm. Generally, the thinner the semi-transmissive film, the higher the transmittance of light, and the thicker the semi-transmissive film, the lower the transmittance of light.

If the first electrode 71 is formed of a semi-transmissive film and the second electrode 73 is formed of a reflective film, light utilization efficiency can be improved using a microcavity effect.

Moreover, the first electrode 71 may be formed in a multilayer structure including a transparent conductive film and a semi-transmissive film. In this case, the first electrode 71 can have a high work function and obtain a microcavity effect.

In one embodiment, the organic emission layer 72 is formed as a multiple layer including one or more of an emission layer, a hole injection layer (HIL), a hole transport layer (HTL), an electron transport layer (ETL), and an electron injection layer (EIL). Among the above-mentioned layers, the layers except for the emission layer may be omitted if required. In the case where the organic emission layer 72 includes all of the above layers, the hole injection layer is disposed on the first electrode 71, and then the hole transport layer, the emission layer, the electron transport layer, and the electron injection layer are sequentially stacked on the hole injection layer. The organic emission layer 72 may further include another layer if necessary.

In one embodiment, the organic light emitting diode lighting apparatus 101 has a bottom emission structure in which light generated from the organic emission layer 72 is emitted outside through the first electrode 71 and the substrate main body 100. In FIG. 1, the arrows shown in dotted lines indicate the directions in which light is emitted.

The sealant 500 is formed over the sealing region of the substrate main body 100. The sealant 500 further includes a conductive member 505. In one embodiment, a plurality of conductive balls (conductive particles) are used as the conductive member 505. However, the invention is not limited thereto.

The conductive member 505 is electrically connected to the first electrode 71 and second electrode 73 of the organic light emitting diode 70.

The printed circuit board 300 is bonded to the substrate main body 100 by the sealant 500, and seals and covers the organic light emitting diode 70. In the first exemplary embodiment, the organic light emitting diode lighting apparatus 101 does not include any particular encapsulation member, since the printed circuit board 300 serves as a substitute for an encapsulation member for sealing and covering the organic light emitting diode 70.

The printed circuit board 300 has a depression 305 corresponding to the light emitting region of the substrate main body 100. As such, the printed circuit board 300 is depressed and spaced apart from the organic light emitting diode 70 in the light emitting region. Thus, as the printed circuit board 300 is bonded to the substrate main body 100 by the sealant 500 and spaced apart from the organic light emitting diode 70, damage to the organic light emitting diode 70 is prevented.

Moreover, the printed circuit board 300 includes external input terminals 710 and 730 electrically connected to the conductive member 505 of the sealant 500.

The external input terminals 710 and 730 include contact portions 711 and 731, pad portions 712 and 732, and connecting portions 715 and 735. The contact portions 711 and 731 are formed on one surface of the printed circuit board 300 facing the sealant 500. The pad portions 712 and 732 are formed on the other surface of the printed circuit board 300 opposed to the one surface. The connecting portions 715 and 735 penetrate the printed circuit board 300 and connect the contact portions 711 and 731 and the pad portions 712 and 732, respectively. The printed circuit board 300 further includes connection holes 301 and 302 for forming the connecting portions 715 and 735.

Moreover, the external input terminals include a first external input terminal 710 connected to the first electrode 71 of the organic light emitting diode 70, and a second external input terminal 730 connected to the second electrode 73 of the organic light emitting diode 70.

In one embodiment, the organic light emitting diode lighting apparatus 101 can minimize the non-light emitting region, i.e., a region excluding the light emitting region. That is, the external input terminals 710 and 730 are formed on the printed circuit board 300 over the sealing region and the external input terminals 710 and 730 are connected to the organic light emitting diode 70 through the conductive member 505, thus minimizing the non-light emitting region of the organic light emitting diode lighting apparatus 101 to only the sealing region. That is, no particular pad region may be provided on the substrate main body 100.

Thus, the difference between the two-dimensional area of the substrate main body 100 and the two-dimensional area of the printed circuit board 300 may be less than about 10%. The two-dimensional area of the substrate main body 100 may be the area of the surface which faces the printed circuit board 300. The two-dimensional area of the printed circuit board 300 may be the area of the surface which faces the substrate main body. The more similar or the more overlapping the two-dimensional areas of the substrate main body 100 and the printed circuit board 300 are to each other, the smaller the area of the non-light emitting region relative to the area of the light emitting region, such that the effects provided by the first exemplary embodiment are maximized.

Moreover, as shown in FIG. 2, the printed circuit 300 may further include a first wiring portion 714 electrically connected to the first pad portions 712 of the first external input terminal 710 (shown in FIG. 1), and a second wiring portion 734 connected to the second pad portions 732 of the second external input terminal 730 (shown in FIG. 1). Also, the first external input terminal 710 and the second external input terminal 730 may be formed in plural, respectively. The first wiring portion 714 and the second wiring portion 734 may interconnect the plurality of first pad portions 712 and the plurality of second pad portions 732, respectively. Further, the wiring portions 714 and 734 may connect the first external input terminal 710 and the second external input terminal 730 to other circuit elements.

In one embodiment, a metal printed circuit board made of a metal material is used as the printed circuit board 300. In one example, the printed circuit board 300 may have an aluminum (Al) substrate serving as a base, and may have an insulating film formed on the surface of the aluminum substrate by anode oxidation. In addition, the external input terminals 710 and 730 may be formed by closely patterning a copper thin film to the insulated aluminum substrate, and various other wires may be further formed.

As such, the printed circuit board 300 is formed as a metal printed circuit board, thus improving the heat dissipation efficiency of the organic light emitting diode lighting apparatus 101. Because the metal printed circuit has relatively high conductivity, excellent heat dissipation effect can be achieved.

Additionally, a metal material has an excellent water vapor permeation inhibiting effect, and therefore the overall water vapor permeation capability of the organic light emitting diode lighting apparatus 101 can be improved by using the metal printed circuit board 300 as the printed circuit board.

Hence, the durability and life-span of the organic light emitting diode lighting apparatus 101 can be improved.

However, the first exemplary embodiment is not limited to the above description. Thus, the printed circuit board 300 may be made of a material containing at least one of plastic and glass. For instance, the printed circuit board 300 may be made of a material such as FR4. If the printed circuit board 300 is formed of a material such as FR4, the organic light emitting diode lighting apparatus 101 can effectively obtain flexible characteristics. Moreover, the manufacture of the printed circuit board 300 is made relatively easier.

The organic light emitting diode lighting apparatus 101 can have a simple structure and effectively improve luminous efficiency.

For example, the organic light emitting diode lighting apparatus 101 can minimize the area of the non-light emitting region relative to the light emitting region. Thus, the organic light emitting diode lighting apparatus 101 can increase the total amount of light compared to the area, and as a result, can increase the life-span of the organic light emitting diode lighting apparatus. Moreover, the amount of light can be increased under the same current density condition.

Further, the overall structure of the organic light emitting diode lighting apparatus 101 is simplified, thereby improving productivity.

In addition, in the case that a metal printed circuit board is used as the printed circuit board 300, improvements in heat dissipation efficiency and water vapor permeation inhibiting effect can be further expected.

Also, in the case that the printed circuit board 30 contains at least one of plastic and glass, manufacturing is made easier and flexible characteristics are provided.

Additionally, according to the first exemplary embodiment, the area of the non-light emitting region of the organic light emitting diode lighting apparatus 101 is minimized, thereby rendering it advantageous in manufacturing a large-scale lighting apparatus having a plurality of organic light emitting diode lighting apparatuses 101 configured in one set.

Now, an organic light emitting diode lighting apparatus 102 according to a second exemplary embodiment will be described with reference to FIG. 3.

As shown in FIG. 3, the organic light emitting diode lighting apparatus 102 has a depression 205 formed by depressing the light emitting region of the substrate main body 200. The organic light emitting diode 70 is formed in the depression 205 of the substrate main body 200. Meanwhile, a printed circuit board 400 is formed flat. In this embodiment, as shown in FIG. 3, one end of the first electrode 71 extends to the sealing region in a first direction, and one end of the second electrode 73 extends to the sealing region in a second direction opposing to the first direction. In this embodiment, each of the first and second electrodes 71 and 73 includes a curved or non-linear portion which is formed near the sealant 500.

As such, the light emitting region of the substrate main body 200 where the organic light emitting diode 70 is formed is depressed so that the organic light emitting diode 70 is spaced apart from the printed circuit board 400. Thus, as the printed circuit board 400 is bonded to the substrate main body 200 by a sealant 500 and spaced apart from the organic light emitting diode 70, damage to the organic light emitting diode 70 is prevented.

Moreover, in the second exemplary embodiment, the printed circuit board 400 may be formed as a metal printed circuit board or contain at least one of plastic and glass.

The organic light emitting diode lighting apparatus 102 can have a simple structure and effectively improve luminous efficiency.

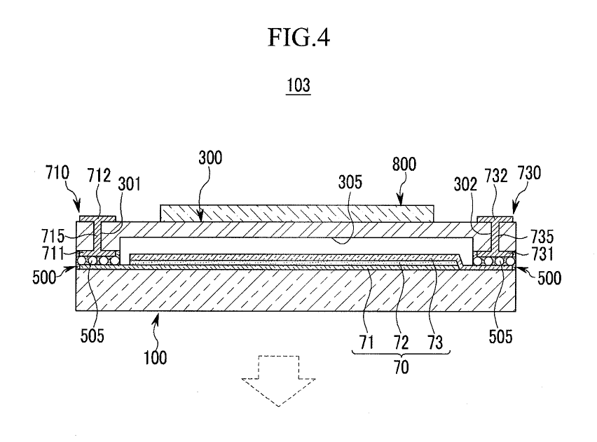

Now, an organic light emitting diode lighting apparatus 103 according to a third exemplary embodiment will be described with reference to FIG. 4.

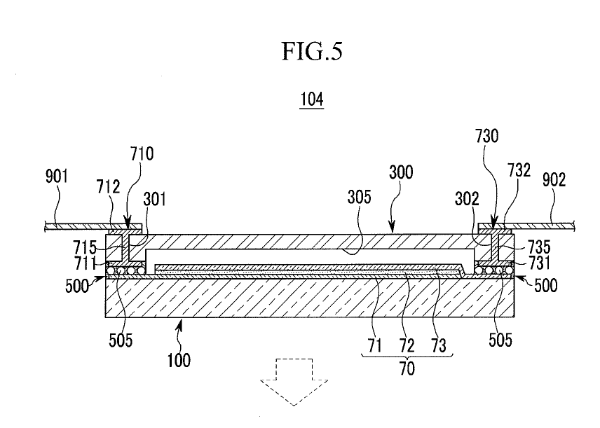

As shown in FIG. 4, the organic light emitting diode lighting apparatus 103 further includes one or more circuit elements 800 mounted on the opposite surface of the surface facing the organic light emitting diode 70 of the printed circuit board 300. The circuit element 800 supplies a driving signal to the organic light emitting diode 70. The circuit element 800 may be connected to the first external input terminal 710 and the second external input terminal 730, respectively, through the first wiring portion 714 (shown in FIG. 2) and the second wiring portion 734 (shown in FIG. 2) or through other wires. In this embodiment, as shown in FIG. 4, one end of the first electrode 71 extends to the sealing region in a first direction, and one end of the second electrode 73 extends to the sealing region in a second direction opposing to the first direction. In this embodiment, the second electrode 73 includes a curved or non-linear portion which is formed near the sealant 500, whereas the first electrode 71 does not include a curved or non-linear portion. This applies to the FIG. 5 embodiment. Thus, the organic light emitting diode lighting apparatus 103 can have a much simpler structure because a separate circuit substrate or a power supply connected through the first external input terminal 710 and the second external input terminal 730 may be omitted.

Moreover, in the third exemplary embodiment, the printed circuit board 300 may be formed as a metal printed circuit board or contain at least one of plastic and glass.

The organic light emitting diode lighting apparatus 103 according to the third exemplary embodiment can have a simple structure and effectively improve luminous efficiency.

Now, an organic light emitting diode lighting apparatus 104 will be described with reference to FIG. 5.

As shown in FIG. 5, the organic light emitting diode lighting apparatus 104 further includes flexible printed circuit (FPC) films 901 and 902 respectively connected to the first external input terminal 710 and second external input terminal 730 formed in the printed circuit board 300. The organic light emitting diode lighting apparatus 104 receives a driving signal and power through the flexible printed circuit films 901 and 902.

Moreover, in the fourth exemplary embodiment, the printed circuit board 300 may be formed as a metal printed circuit board or contain at least one of plastic and glass.

The organic light emitting diode lighting apparatus 104 according to the fourth exemplary embodiment can have a simple structure and effectively improve luminous efficiency.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An organic light emitting diode lighting apparatus, comprising:
a substrate main body including a light emitting region and a sealing region surrounding the light emitting region;
an organic light emitting diode formed over the substrate main body;
a sealant formed over the sealing region of the substrate main body, wherein the sealant comprises a conductive member electrically connected to the organic light emitting diode; and
a printed circuit board bonded to the substrate main body by the sealant to seal and cover the organic light emitting diode, wherein the printed circuit board comprises external input terminals which directly contact the conductive member.

2. The lighting apparatus of claim 1, wherein the external input terminals comprise:
contact portions formed on one surface of the printed circuit board facing the sealant, wherein the contact portions contact the conductive member of the sealant;
pad portions formed on the other surface of the printed circuit board opposed to the one surface; and
connecting portions penetrating the printed circuit board and interconnecting the contact portions and the pad portions.

3. The lighting apparatus of claim 2, wherein the organic light emitting diode further comprises:
a first electrode formed over the light emitting region of the substrate main body and having one end extending to the sealing region;
an organic emission layer formed over the first electrode and the light emitting region of the substrate main body; and
a second electrode formed over the organic emission layer and having one end extending to the sealing region so as to be spaced apart from the first electrode.

4. The lighting apparatus of claim 3, wherein the external input terminals comprise a first external input terminal to be electrically connected to the first electrode and a second external input terminal to be electrically connected to the second electrode, and wherein first and second terminals are formed on opposing ends of the printed circuit board.

5. The lighting apparatus of claim 4, wherein the printed circuit board further comprises a first wiring portion electrically connected to the first external input terminal and a second wiring portion electrically connected to the second external input terminal.

6. The lighting apparatus of claim 1, wherein the conductive member comprises a plurality of conductive balls.

7. The lighting apparatus of claim 1, wherein the printed circuit board has first and second surfaces opposing each other, wherein the first surface faces the organic light emitting diode and wherein one or more circuit elements are mounted on the second surface of the printed circuit board.

8. The lighting apparatus of claim 1, wherein the difference between the two-dimensional area of the substrate main body and the two-dimensional area of the printed circuit board is less than about 10%.

9. The lighting apparatus of claim 1, further comprising flexible printed circuit films electrically connected to the external input terminals.

10. The lighting apparatus of claim 1, wherein the printed circuit board is a metal printed circuit board made of a metal material.

11. The lighting apparatus of claim 1, wherein the printed circuit board has first and second surfaces opposing each other, wherein the first surface faces the organic light emitting diode and wherein the first surface of the printed circuit board is recessed and spaced apart from the organic light emitting diode in the light emitting region.

12. The lighting apparatus of claim 1, wherein the printed circuit board has first and second surfaces opposing each other, wherein the first surface faces the organic light emitting diode, wherein the substrate main body has first and second surfaces opposing each other, wherein the first surface of the substrate main body faces the first surface of the printed circuit board, wherein the first surface of the printed circuit board is not recessed, and wherein the first surface of the substrate main body is recessed so that the organic light emitting diode and the printed circuit board are spaced apart from each other in the light emitting region.

13. The lighting apparatus of claim 1, wherein the printed circuit board is made of a material containing at least one of glass and plastic.

14. The lighting apparatus of claim 1, wherein at least one of the first and second electrodes extends to and contacts the sealant, and wherein at least one of the first and second electrodes has a non-linear portion which is formed near the sealant.

15. The lighting apparatus of claim 1, wherein the printed circuit board encapsulates the organic light emitting diode so that the lighting apparatus does not require a separate encapsulation film.

16. The lighting apparatus of claim 1, wherein the printed circuit board is formed of a transparent material so as to transmit light emitted from the organic light emitting diode.

17. An organic light emitting diode lighting apparatus, comprising:
a substrate;
an organic light emitting diode formed over the substrate, wherein the organic light emitting diode comprises first and second electrodes and a light emitting layer interposed between the electrodes; and
a printed circuit board electrically connected to at least one of the first and second electrodes via a sealant, wherein the printed circuit board is configured to encapsulate the organic light emitting diode, wherein at least one of the first and second electrodes extends to and contacts the sealant and wherein at least one of the first and second electrodes has a non-linear portion which is formed near the sealant.

18. The lighting apparatus of claim 17, wherein the sealant comprises a plurality of conductive balls electrically connected to the organic light emitting diode and external input terminals of the printed circuit board.

19. The lighting apparatus of claim 17, wherein the first and second electrodes have first and second non-linear portions, respectively, wherein the substrate has first and second ends opposing each other, wherein the first and second non-linear portions are formed near the first and second ends of the substrate, respectively.

20. The lighting apparatus of claim 17, wherein the printed circuit board has first and second surfaces opposing each other, wherein the first surface faces the organic light emitting diode, wherein the substrate has first and second surfaces opposing each other, wherein the first surface of the substrate faces the first surface of the printed circuit board, and wherein one of 1) the first surface of the printed circuit board and 2) the first surface of the substrate has a recessed portion configured to accommodate the organic light emitting diode.
